(19) United States
(12) Patent Application Publication
(10) Pub. No.: US 2011/0163225 A1
(43) Pub. Date: Jul. 7, 2011

(54) WAFER LEVEL OPTICAL APPARATUS

(75) Inventor: CHUAN-HUI YANG, TAINAN (TW)

(73) Assignee: WISEPAL TECHNOLOGIES, INC., TAINAN (TW)

(21) Appl. No.: 12/651,999

(22) Filed: Jan. 4, 2010

(51) Int. Cl. H01L 31/0232

(52) U.S. Cl. 250/227.2

(57) ABSTRACT

A wafer level optical apparatus includes a wafer level lens unit for receiving light. The wafer level lens unit includes a lens substrate having a partial surface with a slope greater than zero and at least one lens adhered to a surface of the lens substrate.

### BACKGROUND OF THE INVENTION

1. Field of the Invention

The present invention generally relates to a wafer level module, and more particularly to a wafer level optical apparatus having a lens substrate with an increased effective area.

2. Description of Related Art

Wafer level optics (WLO) is a technique of fabricating miniaturized optics such as lens modules or camera modules at the wafer level using semiconductor techniques. The WLO technique is well adapted to mobile or handheld devices.

FIG. 1A shows a schematic cross-section of a conventional wafer level camera module, and FIG. 1B shows a schematic cross-section of another conventional wafer level camera module. In either camera module, lenses 101A and 101B are glued to a flat glass substructure 100. In spite of the simple structure of the camera module, the lenses 101A and 101B are apt to be separated from the glass substructure 100 due to external or environmental forces. For example, the external force may be the force induced during the fabrication process (e.g., slicing) or may be a force caused by improper handling (e.g., dropping).

For the reason that conventional wafer level optical modules such as camera modules could not effectively resist external forces, a need has arisen to propose a novel structure for the wafer level optical module in order to effectively and economically resist damage or breakage owing to external forces.

### SUMMARY OF THE INVENTION

In view of the foregoing, it is an object of the embodiment of the present invention to provide a wafer level optical apparatus which is capable of more effectively resisting damage or breakup as compared to the conventional optical module.

According to one embodiment, the wafer level optical apparatus includes a step-shaped lens substrate, a lens adhered to the lens substrate, an image sensor, a cover substrate disposed above the lens substrate, and a number of spacers. Some of the spacers are disposed between the cover substrate and the lens substrate, and others are disposed between the lens substrate and the image sensor. According to another embodiment, another lens is adhered to the lens substrate. In a further embodiment, the lenses can comprise lens elements, which may be adjacently disposed. Recesses can be formed on a portion of the lens substrate that is positioned between adjacent lens elements. According to a further embodiment, a portion of the lens substrate positioned between the adjacent lens elements has a roughened surface and/or the recesses have a roughened surface.

### BRIEF DESCRIPTION OF THE DRAWINGS

FIG. 1A shows a schematic cross-section of a conventional wafer level camera module;

FIG. 1B shows a schematic cross-section of another conventional wafer level camera module;

FIG. 2 schematically shows a wafer level optical apparatus with lenses according to one embodiment of the present invention;

FIG. 3 schematically shows a lens substrate and lenses according to the embodiment of FIG. 2;

FIG. 4A schematically shows a lens substrate with lenses according to another embodiment of the present invention; and

FIG. 4B schematically shows a lens substrate and lenses according to a further embodiment of the present invention.

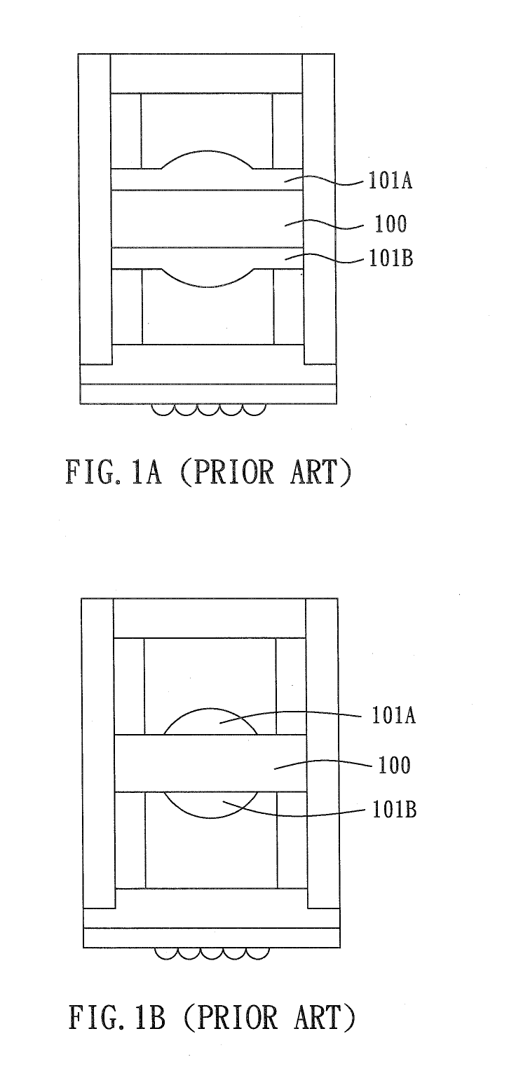

### DETAILED DESCRIPTION OF THE INVENTION

Embodiments of the invention are now described and illustrated in the accompanying drawings, instances of which are to be interpreted to be to scale in some implementations while in other implementations, for each instance, not. According to certain implementations, use of directional terms, such as, top, bottom, left, right, up, down, over, above, below, beneath, rear, and front, are to be construed literally, while in other implementations the same use should not. Any feature or combination of features described or referenced herein are included within the scope of the present invention provided that the features included in any such combination are not mutually inconsistent as will be apparent from the context, this specification, and the knowledge of one skilled in the art. In addition, any feature or combination of features described or referenced may be specifically included, replicated and/or excluded, in any combination, in/from any embodiment of the present invention.

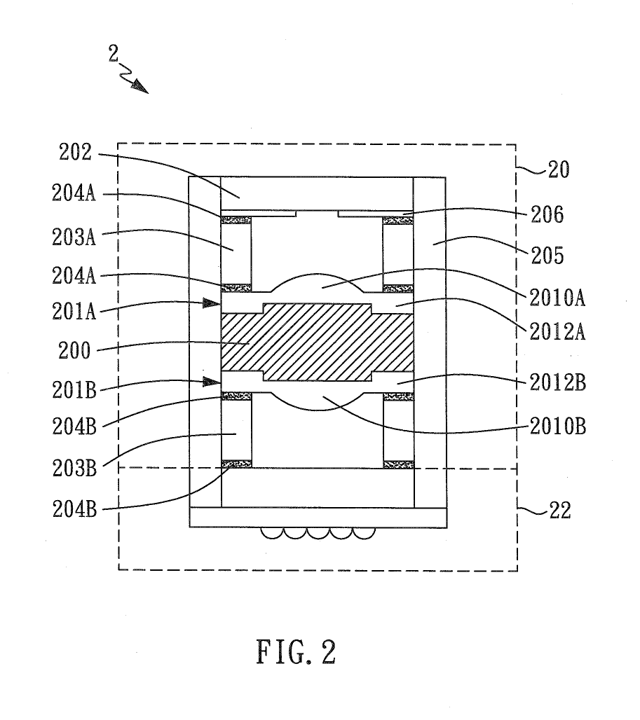

FIG. 2 schematically shows a wafer level optical apparatus in the form of a wafer level camera module 2 according to one embodiment of the present invention. Although a camera module 2 is illustrated here, it is appreciated by those skilled in the art that the present embodiment may be well adapted to other wafer level optical apparatus.

In the embodiment, the camera module 2 primarily includes a wafer level lens unit 20 for receiving light, and an image sensor 22 for converting the light out of (i.e., exiting) the wafer level lens unit 20 into electrical signals. Specifically, the image sensor 22 may be, but not limited to, a complementary metal oxide semiconductor (CMOS) image sensor or a charge coupled device (CCD). The lens unit 20, in the embodiment, includes a lens substrate or substructure (e.g., a glass plate) 200, a first lens 201A and a second lens 201B. In the embodiment, the first lens 201A can include a lens element 2010A and an extension portion 2012A extending from the lens element 2010A, and/or the second lens 201B can include a lens element 2010B and an extension portion 2012B extending from the lens element 2010B. In another embodiment, one or more of the extension portions 2012A/B may be omitted. The lenses 201A and 201B are adhered to the top surface and the bottom surface of the lens substrate 200 respectively, for example, by glue (e.g., ultra violet (UV) glue). Although two convex lenses 201A and 201B are illustrated in this embodiment, it is noted that the number of the lenses in a module may be other than two, and/or other types of lenses (such as concave lenses) may be used instead. For example, a wafer level lens unit may comprise a plurality of lenses, e.g., of the same or different type(s), adhered to one or more of a first (e.g., top) surface and a second (e.g., bottom) surface of a lens substrate. According to one implementation, the wafer level lens unit can comprise a plurality of lenses, e.g., of the same or different type(s), adhered to the first surface of the lens substrate and a plurality of lenses, e.g., of the same or different type(s), adhered to a second surface of the lens substrate. In accordance with another aspect, the wafer level optical apparatus (e.g., lens unit) can comprise one or more of (a) a plurality of lenses, e.g., of the same or different type(s), adhered to the first surface of the lens substrate and (b) a plurality of lenses, e.g., of the same or different type(s), adhered to the second surface of the lens substrate.

The lens unit 20 may further include a cover substrate (e.g., glass) 202 that is disposed above and covers the first lens 201A. Spacers 203A are adhered between the cover substrate 202 and the lens 201A, for example, by glue 204A, and spacers 203B are adhered between the lens 201B and the image sensor 22, for example, by glue 204B. The sidewall of the lens unit 20 and partial sidewall of the image sensor 22 may be surrounded by a black coating 205 that blocks light from entering into the camera module 2. Moreover, a stop 206 may be formed on the bottom surface of the cover substrate 202. The stop 206 has an opaque pattern that partially masks the cover substrate 202 to provide an iris for the camera module 2. In the embodiment, the stop 206 is formed or deposited on the bottom surface of the cover substrate 202, for example, by evaporation or sputtering. The deposited material may be or may comprise, but is not limited to, chromium oxide.

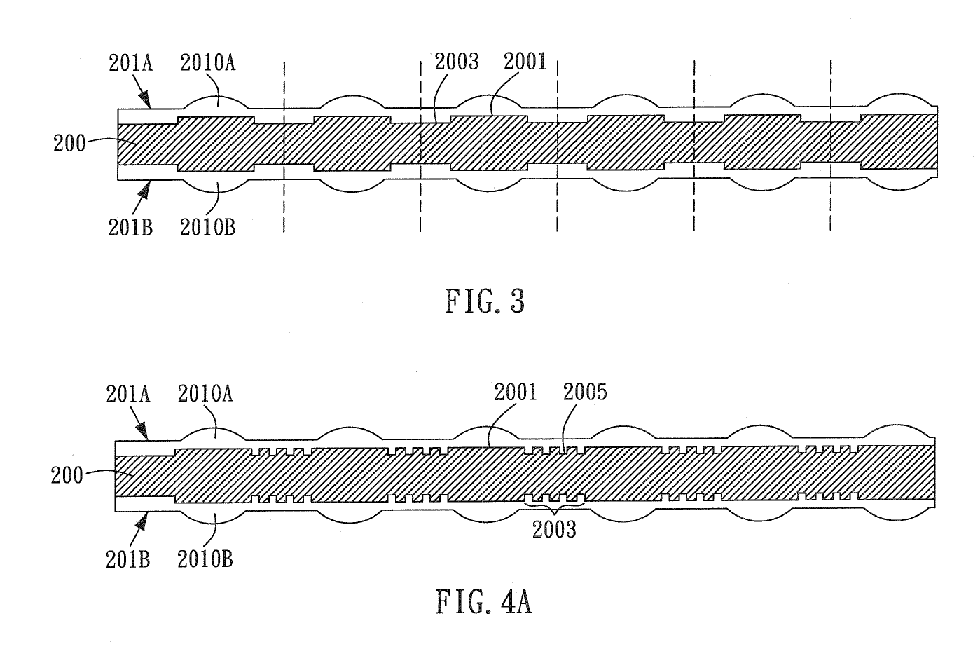

According to one aspect of the embodiment, the lens substrate 200 has a non-planar (or non-flat) top and/or bottom surface such that the effective area between the lens 201A/201B and the lens substrate 200 may be substantively increased over the (conventionally) flat lens substrate. In general, a partial surface of the lens substrate 200 may have a slope greater than zero. In the exemplary embodiment shown in FIG. 2, which is reproduced in FIG. 3, the lens substrate 200 has step-shaped surface and/or has a recess formed on the surface of the lens substrate 200. In this specific exemplary embodiment, the surface of the lens substrate 200 has one step, wherein the raised step 2001 is approximately aligned with the lens element 2010A/2010B. In another embodiment, however, the surface of the lens substrate 200 may have more than one step. In a further embodiment, it is the lowered step 2003, rather than, or in addition to, the raised step 2001, that may be approximately aligned with the lens element 2010A/2010B. The step-shaped surface and/or the recess of the lens substrate 200 may be formed, for example, by etching or laser cutting.

According to the embodiment described above, in addition to a vertical adhesive force along the level surface, an adhesive force along another (e.g., other than the horizontal) direction (e.g., the horizontal adhesive force along the vertical step edge) may be obtained (e.g., further obtained) in the embodiment due to the formed surface with slope greater than zero. Therefore, the interface between the lens substrate 200 and the lens 201A/201B in the wafer level camera module 2 (FIG. 2) may capably resist damage or breakup owing to external forces.

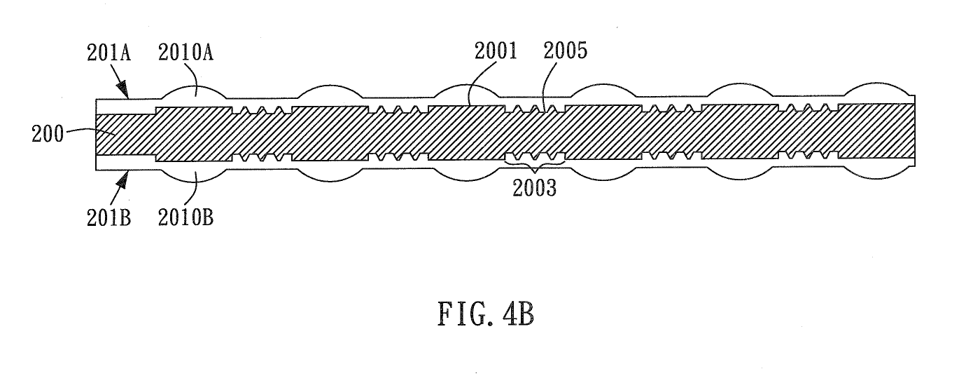

FIG. 4A schematically shows a lens substrate 200 and lenses 201A/201B according to another embodiment of the present invention. In addition and/or as an alternative to the formed step-shaped surface, one or more recesses (or grooves) 2005 can be formed, such as on the lowered step 2003 of the lens substrate 200, for example, by etching or laser cutting. In other words, the recesses 2005 can be formed on a surface between adjacent lens elements 2010A/2010B. Each of the recesses 2005 may have a sharp edge (e.g., an approximately 90-degree edge) as shown in FIG. 4A. In another embodiment, however, each of the recesses 2005 may have an edge and/or portion of an edge with a slope substantially other than 90 degrees, such as depicted in FIG. 4B.

Due to the adhesive force obtained from the formed recess-shaped surface, the embodiment illustrated in FIG. 4A or FIG. 4B may be capable of a greater degree and/or different type of resistant to damage or breakup than, for example, an embodiment with different type(s) or without recesses such as illustrated in FIG. 3.

According to a still further embodiment, surfaces between adjacent lens elements 2010A/2010B (e.g., the surface of the lowered step in FIG. 3, FIG. 4A, or FIG. 4B) may be subjected to a roughening process, whereby the effective area of the resultant roughened surface of the lens substrate 200 may be increased (e.g., further increased). Microscopically, the roughened surface can resemble, for example, the recess as described above accompanied by FIG. 4A or, particularly, FIG. 4B. Therefore, a resultant optical apparatus with the formed roughened surface may be more or differently resistant to damage or breakup than, for example, an optical apparatus with a different or without a roughened surface.

Although specific embodiments have been illustrated and described, it will be appreciated by those skilled in the art that various modifications may be made without departing from the scope of the present invention, which is intended to be limited solely by the appended claims.

What is claimed is:

1. A wafer level optical apparatus, comprising:
a wafer level lens unit for receiving light, wherein the wafer level lens unit comprises:
a lens substrate having a partial surface with a slope greater than zero; and
a first lens adhered to a first surface of the lens substrate.

2. The apparatus of claim 1, further comprising an image sensor for converting light exiting the wafer level lens unit into electrical signals, thereby resulting in a wafer level camera module.

3. The apparatus of claim 2, wherein the image sensor comprises a complementary metal oxide semiconductor (CMOS) image sensor or a charge coupled device (CCD).

4. The apparatus of claim 1, wherein the wafer level lens unit further comprises a second lens adhered to a second surface of the lens substrate.

5. The apparatus of claim 4, wherein one or more of the first lens and the second lens comprises:
a lens element; and
an extension portion extended from the lens element.

6. The apparatus of claim 1, wherein the wafer level lens unit further comprises a cover substrate that is disposed above and covers the lens substrate.

7. The apparatus of claim 6, further comprising a stop that is formed on a bottom surface of the cover substrate, wherein the stop has an opaque pattern that partially masks the cover substrate.

8. The apparatus of claim 6, wherein the wafer level lens unit further comprises a plurality of spacers disposed between the cover substrate and the lens substrate.

9. The apparatus of claim 2, wherein the wafer level lens unit further comprises a plurality of spacers disposed between the lens substrate and the image sensor.

10. The apparatus of claim 1, further comprising a black coating that surrounds a sidewall of the wafer level lens unit.

11. The apparatus of claim 1, wherein the lens substrate has a step-shaped surface.

12. The apparatus of claim 11, wherein a lowered step of the step-shaped surface of the lens substrate is formed by etching or cutting.

13. The apparatus of claim 11, wherein a lowered step or a raised step has a roughened surface.

14. The apparatus of claim 11, wherein a plurality of recesses are formed on a lowered step or a raised step of the step-shaped surface of the lens substrate.

15. The apparatus of claim 14, wherein each of the recesses has an approximately 90-degree edge.

16. The apparatus of claim 14, wherein the recesses have a roughened surface.

17. The apparatus of claim 1, wherein the wafer level lens unit comprises a plurality of lenses adhered to one or more of the first surface and a second surface of the lens substrate.

18. The apparatus of claim 1, wherein the wafer level lens unit comprises a plurality of lenses adhered to the first surface of the lens substrate and a plurality of lenses adhered to a second surface of the lens substrate.

19. A wafer level optical apparatus, comprising:
a lens substrate having a step-shaped surface;
a first lens adhered to a first surface of the lens substrate;
an image sensor for converting light into electrical signals;
a cover substrate that is disposed above and covers the lens substrate; and
a plurality of spacers, some of the spacers being disposed between the cover substrate and the lens substrate, and others of the spacers being disposed between the lens substrate and the image sensor.

20. The apparatus of claim 19, wherein the image sensor comprises a complementary metal oxide semiconductor (CMOS) image sensor or a charge coupled device (CCD).

21. The apparatus of claim 19, further comprising a second lens adhered to a second surface of the lens substrate.

22. The apparatus of claim 21, wherein one or more of the first lens and the second lens comprises:
a lens element; and
an extension portion extended from the lens element.

23. The apparatus of claim 21, wherein the wafer level optical apparatus comprises a plurality of lenses adhered to one or more of the first surface and the second surface of the lens substrate.

24. The apparatus of claim 19, wherein the wafer level optical apparatus comprises one or more of (a) a plurality of lenses adhered to the first surface of the lens substrate and (b) a plurality of lenses adhered to the second surface of the lens substrate.

25. The apparatus of claim 19, further comprising a stop that is formed on a bottom surface of the cover substrate, wherein the stop has an opaque pattern that partially masks the cover substrate.

26. The apparatus of claim 19, further comprising a black coating that surrounds sidewalls of the cover substrate, the spacers, the first lens, and the lens substrate.

27. The apparatus of claim 22, wherein both of the lenses comprise lens elements which are adjacently disposed and a portion of the lens substrate positioned between the adjacent lens elements has a roughened surface.

28. The apparatus of claim 22, wherein each of the lenses comprises a lens element, the lens elements are adjacent to one another, and a plurality of recesses are formed on a portion of the lens substrate that is positioned between the adjacent lens elements.

29. The apparatus of claim 28, wherein each of the recesses has an approximately 90-degree edge.

30. The apparatus of claim 28, wherein the recesses have a roughened surface.
